(19) United States
(12) Patent Application Publication
(10) Pub. No.: US 2026/0206169 A1
(43) Pub. Date: Jul. 16, 2026

(54) MANAGING SECURING ASSEMBLIES FOR PHYSICAL COMPONENTS

(71) Applicant: Aivres Systems Inc., Fremont, CA (US)

(72) Inventor: CHENG HUA CHEN, New Taipei City (TW)

(21) Appl. No.: 19/560,787

(22) Filed: Mar. 9, 2026

(51) Int. Cl. H05K 7/14; H05K 7/20

(52) U.S. Cl. CPC H05K 7/1487; H05K 7/1411; H05K 7/1424; H05K 7/1489; H05K 7/1492; H05K 7/20709

(57) ABSTRACT

Devices, systems, methods, and techniques for securing physical components to computing devices with securing assemblies are provided. In one aspect, a securing assembly includes a cage and a button coupled to the cage. The button includes a body structure extending along a first direction and a secure pin attached to the body structure along a second direction, and where the button is movable with respect to the cage along the first direction. The securing assembly further includes a plate spring coupled to the button through the secure pin. The plate spring includes a first segment attached to the cage and a second segment that is movable with respect to the first segment. The button is configured to be moved to cause the second segment of the plate spring to move with respect to the first segment of the plate spring between a closed position and an open position.

### TECHNICAL FIELD

The present disclosure is related to securing assemblies, particularly for securing/releasing physical components to computing devices.

### BACKGROUND

Computing devices, such as servers, industrial control systems, and deep learning platforms, are widely used in a variety of fields. In areas such as artificial intelligence (AI) and big data, the need for computing is growing rapidly. These computing devices generally require multiple external electronic devices connected to the computing devices to support intensive computational workloads.

### SUMMARY

The present disclosure describes devices, systems, methods, and techniques for securing physical components to computing devices through a securing assembly, e.g., securing the electrical component to the computing device, and/or releasing a secured electrical component from the computing device.

One aspect of the present disclosure features an apparatus. The apparatus includes a cage; a button coupled to the cage, where the button includes a body structure extending along a first direction and a secure pin attached to the body structure along a second direction intersecting with the first direction, and where the button is movable with respect to the cage along the first direction; and a plate spring coupled to the button through the secure pin, where the plate spring includes a first segment and a second segment that is movable with respect to the first segment, and the first segment of the plate spring is attached to the cage, where the button is configured to be moved to cause the second segment of the plate spring to move with respect to the first segment of the plate spring between a closed position and an open position.

In some implementations, the plate spring includes a mounting hole, where the secure pin extends through the mounting hole to couple the plate spring and the button together, the plate spring being between the body structure and the secure pin along the second direction, and where the plate spring is configured to be bended by a movement of the button along the first direction to cause the second segment to move with respect to the first segment, with the secure pin coupling together the plate spring and the button.

In some implementations, the first segment of the plate spring is secured to the cage through one or more rivets.

In some implementations, the plate spring is bendable at an interface between the first segment and the second segment of the plate spring to cause a movement of the second segment with respect to the first segment.

In some implementations, the button is coupled to the cage through a pair of springs, where the pair of springs are in contact with the body structure of the button and a guiding pad of the cage, and where the pair of springs and the guiding pad are configured to limit a range of a movement of the button along the first direction, and where the pair of springs are configured to reposition the button along the first direction.

In some implementations, the cage includes: a first portion securable to a computing system; and a second portion attached to the first portion, where the first portion and the second portion of the cage surround the button along a plane perpendicular to the first direction, and are configured to restrain the button along the second direction.

In some implementations, the second segment of the plate spring includes a locking structure that is configured to secure a physical component to the computing system at the closed position.

In some implementations, the apparatus further includes back plate including a rotating rod, where the back plate is attached to the cage by the rotating rod through a pair of locking holes, and the back plate is rotatable around an axis defined by the pair of locking holes.

In some implementations, the cage includes at least one positioning structure configured to limit a range of a rotation of the back plate around the axis.

In some implementations, a degree of the rotation of the back plate is in a range from 0° to 90°.

In some implementations, the button is not in contact with the back plate along the first direction, while the plate spring is at the closed position.

In some implementations, the button is configured to be moved to cause the rotation of the back plate around the axis while the plate spring is at the open position, with the back plate being in contact with an end of the body structure of the button along the first direction.

Another aspect of the present disclosure features a computing system. The computing system includes a computing case; and a securing assembly attached to the computing case, where the securing assembly includes: a cage that is attached to the computing case; a button coupled to the cage, where the button includes a body structure extending along a first direction and a secure pin attached to the body structure along a second direction intersecting with the first direction, and where the button is movable with respect to the cage along the first direction; and a plate spring coupled to the button through the secure pin, where the plate spring includes a first segment and a second segment that is bendable with respect to the first segment, and the first segment of the plate spring is attached to the cage, where the button is configured to be moved to cause the second segment of the plate spring to move with respect to the first segment of the plate spring between a closed position and an open position.

In some implementations, the computing system further includes an electrical component, where the electrical component is configured to be secured to the computing case of the computing system by the securing assembly.

In some implementations, the second segment of the plate spring includes a locking structure that is configured to secure the electrical component to the computing case at the closed position.

In some implementations, the computing system further includes an electrical board attached to the computing case; and a connector coupled to the electrical board, where the electrical component is connected to the connector while the electrical component is secured by the second segment of the plate spring.

In some implementations, the computing system further includes a back plate including a rotating rod, where the back plate is attached to the cage by the rotating rod through a pair of locking holes, and the back plate is rotatable around an axis defined by the pair of locking holes.

In some implementations, the button is configured to be moved to cause the rotation of the back plate around the axis while the plate spring at the open position, with the back plate being in contact with an end of the body structure of the button along the first direction.

In some implementations, the back plate includes a pair of contact pads that are in contact with the electrical component, and where the electrical component is movable along a direction opposite to a movement direction of the button by the pair of contact pads in reaction to the rotation of the back plate.

In some implementations, the pair of contact pads includes an insulation material.

A further aspect of the present disclosure features a method. The method includes securing a physical component to a computing system by a securing assembly, where the securing assembly includes: a cage, a button coupled to the cage, and a plate spring coupled to the button, where the button includes a body structure extending along a first direction and a secure pin attached to the body structure along a second direction intersecting with the first direction, where the button is movable with respect to the cage along the first direction, where a plate spring coupled to the button through the secure pin, where the plate spring includes a first segment and a second segment that is movable with respect to the first segment, and the first segment of the plate spring is attached to the cage, and where the button is configured to be moved to cause the second segment of the plate spring to move with respect to the first segment of the plate spring between a closed position and an open position; and releasing the physical component from the computing system by pushing a button of the securing assembly to cause the plate spring to bend to thereby release the physical component from the computing system.

In some implementations, releasing the physical component from the computing system includes: pushing the button of the securing assembly to cause a rotation of a back plate of the securing assembly to thereby move the physical component along a second direction opposite to the first direction.

In some implementations, the back plate includes a pair of contact pads that are in contact with the physical component, and where the physical component is movable along the second direction by the pair of contact pads in reaction to the rotation of the back plate.

In the present disclosure, a securing assembly can be configured to hold a physical component in place, making it safer, or preventing it from moving. The securing assembly can include a mounting assembly, a locking assembly, a fastening assembly, an anchoring assembly, a tying assembly, a latching assembly, a jointing assembly, a clamping assembly, or a binding assembly. For illustration purposes, in some cases, a mounting assembly is described herein as an example of the securing assembly. For illustration purposes, in some cases, the techniques are described with respect to a computing device as an example. Note that the techniques can also be applied to a computing system that can include one or more computing devices and/or one or more auxiliary devices or peripheral devices. The terms “electronic device” and “electronic component” can be used interchangeably in the present disclosure. The term “a physical component” can include, but not limited to, an electronic device or an electronic component, a mechanical component, or a structural component.

The details of one or more implementations of the subject matter of this specification are set forth in the Detailed Description, the Claims, and the accompanying drawings. Other features, aspects, and advantages of the subject matter will become apparent to those of ordinary skill in the art from the Detailed Description, the Claims, and the accompanying drawings.

### DESCRIPTION OF DRAWINGS

FIG. 1 illustrates a schematic view of an example computing device.

FIG. 2A illustrates a perspective view of an example computing device.

FIG. 2B illustrates a cross-sectional view of the computing device of FIG. 2A.

FIG. 2C illustrates another perspective view of the computing device of FIG. 2A.

FIG. 3A illustrates perspective views of an example securing assembly.

FIG. 3B illustrates an exploded view of the securing assembly of FIG. 3A.

FIG. 3C illustrates perspective views of the securing assembly of FIG. 3A.

FIGS. 4A – 4B illustrate steps of releasing a physical component from a securing assembly.

FIGS. 5A – 5C illustrate steps of assembling an example securing assembly.

FIGS. 6A – 6C illustrate steps of securing an electrical component to a computing device.

FIGS. 7A – 7B illustrate steps of releasing an electrical component from a computing device.

FIG. 8A is a flowchart of an example process of a method of securing a physical component to a computing device.

FIG. 8B is a flowchart of an example process of a method of releasing a physical component from a computing device.

FIG. 9 illustrates an example computing device.

FIG. 10 illustrates an example computing system.

Like reference numbers and designations in the various drawings indicate like elements.

### DETAILED DESCRIPTION

Development in computing technology has led to an increasing demand for larger and more sophisticated network communication architectures. Computing devices configured to satisfy these demands may require enhanced processing capabilities, which in turn generate substantial heat during operation. A cooling module can be employed to maintain an appropriate operational environment. In some implementations, the cooling module may include an array of fan modules configured to draw cooling air from outside a case or housing of the computing device. The array of fan modules may be arranged in a condensed configuration to increase an airflow capacity. In some cases, such a condensed arrangement may reduce an available service space, thereby creating challenges during maintenance operations. For example, a service operator may be required to remove all of the fan modules in the array in order to replace a single fan module. In some cases, handles may be integrated into the fan module to facilitate servicing. The handles of the fan modules may obstruct airflow and reduce the cooling performance of the cooling module. Besides a cooling module, other physical components may also have the similar issues for securing/releasing.

Implementations of the present disclosure provide methods, devices, systems, and techniques for securing (e.g., mounting or assembling) a physical component to a computing device or a computing system with a securing assembly and/or releasing (e.g., unlocking or disassembling) the physical component from the computing system or the computing system using the securing assembly. In some implementations, the securing assembly includes a cage. The securing assembly also includes a button coupled to the cage. The button includes a body structure extending along a first direction and a secure pin attached to the body structure along a second direction intersecting with the first direction, and where the button is movable with respect to the cage along the first direction. The securing assembly further includes a plate spring coupled to the button through the secure pin, where the plate spring includes a first segment and a second segment that is movable with respect to the first segment, and the first segment of the plate spring is attached to the cage. The button is configured to be moved to cause the second segment of the plate spring to move with respect to the first segment of the plate spring between a closed position and an open position.

Implementations of the present disclosure can provide one or more technical advantages, effects, and benefits. For example, a securing assembly disclosed in the present disclosure is configured to secure a physical component (e.g., a fan module or a power supply unit (PSU)) to a case of a computing device (or a computing system). During device operation, the plate spring of the securing assembly is configured to secure the physical component in place, thereby improving operational stability and reducing error rates. Additionally, during a service or maintenance operation, a service operator can remove the physical component by releasing the physical component using the securing assembly. In some cases, releasing the physical component from the computing device using the securing assembly includes passively letting the physical component go (e.g., unlocking or unlatching or disengaging) and/or actively setting the physical component free (e.g., ejecting or pushing or displacing). For example, releasing the physical component can include pushing a button of the securing assembly that causes the plate spring to unlock the physical component, from the case and further causes a back plate of the securing assembly to rotate, thereby pushing the physical component outward from the case. In some cases, each of the physical components can be individually controlled and serviced, thereby reducing service costs and device downtime. Furthermore, the securing assembly eliminates a need for handles that are integrated into the physical component such as a cooling module having fan modules, which can help maximize the airflow capacity of each of the fan modules and improve the overall cooling performance of the computing device.

The following detailed description describes systems and techniques for securing a physical component to a computing device or system and is presented to enable any person skilled in the art to make and use the disclosed subject matter in the contact of one or more particular implementations. Various modifications, alterations, and permutations of the disclosed implementations can be made and will be readily apparent to those of ordinary skill in the art, and the general principles defined can be applied to other implementations and applications, without departing from the scope of the present disclosure. In some instances, one or more technical details that are unnecessary to obtain an understanding of the described subject matter and that are within the skill of one of ordinary skill in the art may be omitted so as to not obscure one or more described implementations. The present disclosure is not intended to be limited to the described or illustrated implementations, but to be accorded the widest scope consistent with the described principles and features.

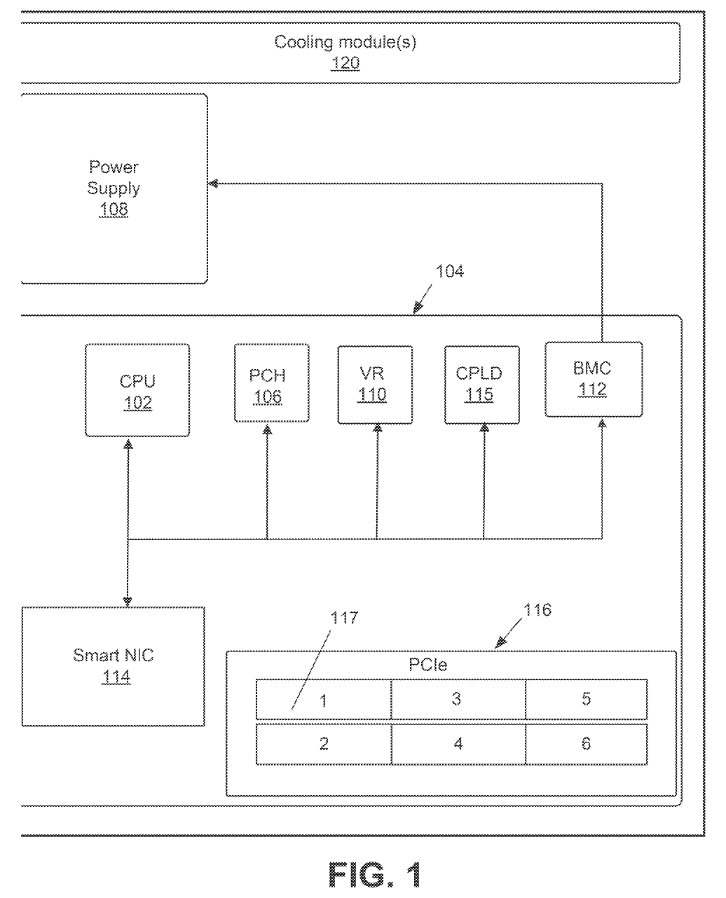

FIG. 1 is a schematic view of an example computing device 100. The computing device 100 includes one or more electronic components. For example, as shown in FIG. 1, one of the one or more electronic components can be a processor 102. As shown in FIG. 1, the processor 102 can be a central processing unit (CPU). Although most of the descriptions below are using the example of CPUs, the described systems and techniques are applicable to other types of processors. In some implementations, the one or more electronic components can be other types of components that are configured to perform different operations of the computing device 100. For example, the one or more electronic components can include one or more CPUs, graphics processing units (GPUs), multi-core processors, microprocessors, quantum processors, storage units (e.g., dynamic random access memory (DRAM)), peripheral component interconnect express (PCIe) devices, or a combination of thereof. The computing device 100 includes a motherboard (MB) 104. The MB 104 can be a main circuit board that connects internal and external components of the computing device 100 and allows them to communicate with one another. For example, the MB 104 can connect one or more processors, memory, graphics card, and other hardware.

One of the one or more electronic components can be a platform controller hub (PCH) 106. The PCH 106 can be mounted on the MB 104 and is configured to manage various input/output (I/O) interfaces on the MB 104 and serve as an intermediary between the processor 102 and peripherals to route data from connected devices. As shown in FIG. 1, the computing device 100 can also include a power supply module 108. The power supply module 108 is electrically coupled to the processor 102 through a voltage regulator (VR) 110. In operation, the power supply module 108 is configured to supply power to the processor 102, and the VR 110 is configured to regulate the power supplied by the power supply module 108 to the processor 102. For example, the VR 110 is configured to maintain a safe operation voltage of the processor 102 during the operation of the computing device 100.

In some implementations, the computing device 100 also includes a Baseboard Management Controller (BMC) 112. The BMC 112 is a microcontroller that provides out-of-band management of the computing device 100. In some implementations, the BMC 112 is configured to provide administrators with remote access and control over hardware, for example, even when the computing device 100 is powered off or unresponsive. The BMC 112 can be accessible by the administrators via a dedicated Ethernet (or local area network (LAN)) port or a shared network interface, thereby allowing secure remote connections.

The computing device 100 can further include a complex programmable logic device (CPLD) 115. The CPLD 115 can be mounted onto the MB 104 and be coupled to the processor 102. The CPLD 115 can include a plurality of programmable logic blocks that are configured to perform various functions controlled by the processor 102. In some implementations, the plurality of programmable logic blocks of the CPLD 115 can be freely programmed by the processor 102, which allows flexibility in designing digital circuits.

As shown in FIG. 1, the computing device 100 also includes a Network Interface Controller (NIC) 114 (e.g., a smart NIC) and a connector circuit 116 for connecting one or more electronic devices. The connector circuit 116 can include one or more connectors 117 for connecting the one or more electronic devices. For example, one connector is configured to connect one electronic device. In some examples, a connector 117 can be a PCIe connector 117 for connecting a corresponding PCIe device, e.g., a GPU, a Storage device, a sound card, a graphic card, a Network Card, or any other suitable electronic device. For illustration purposes, the PCIe connector and the PCIe device are described below as examples of the connector and the electronic device.

The NIC 114 can be mounted on the MB 104. The connector circuit 116 is coupled to the processor 102. In some implementations, each of the PCIe connectors 117 includes a PCIe slot soldered onto the MB 104, where an electronic device is mounted to the MB 104 through the PCIe slot. In some implementations, the NIC 114 can be configured to control the PCIe devices. In some implementations, the NIC 114 also enables the computing device 100 to communicate with other devices on a network. In some implementations, the NIC 114 can be coupled to the processor 102 through one of the PCIe connectors 117 that is soldered onto the MB 104.

In some implementations, the computing device 100 includes one or more cooling modules 120. The one or more cooling modules 120 can include one or more air-cooling modules such as fans and/or one or more liquid-cooling modules such as cooling plates, which can provide cooling for the computing device 100 during operation.

The computing device 100 can be configured to ensure real-time detection of the presence, status, and quantity of the external electronic devices connected to the PCIe connectors 117 or the connector circuit 116 for maintaining the overall system stability and reliability of the computing device 100. In some implementations, the presence, status, and quantity of the external electronic devices connected to the PCIe connectors 117 can be detected by the BMC 112 and/or the CPLD 115.

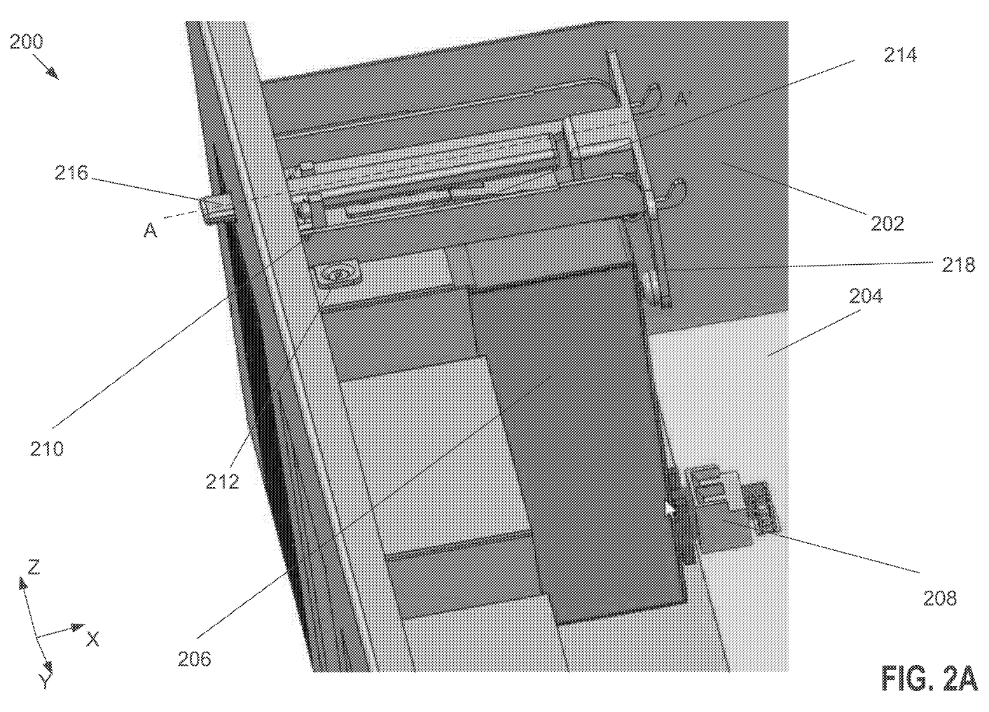

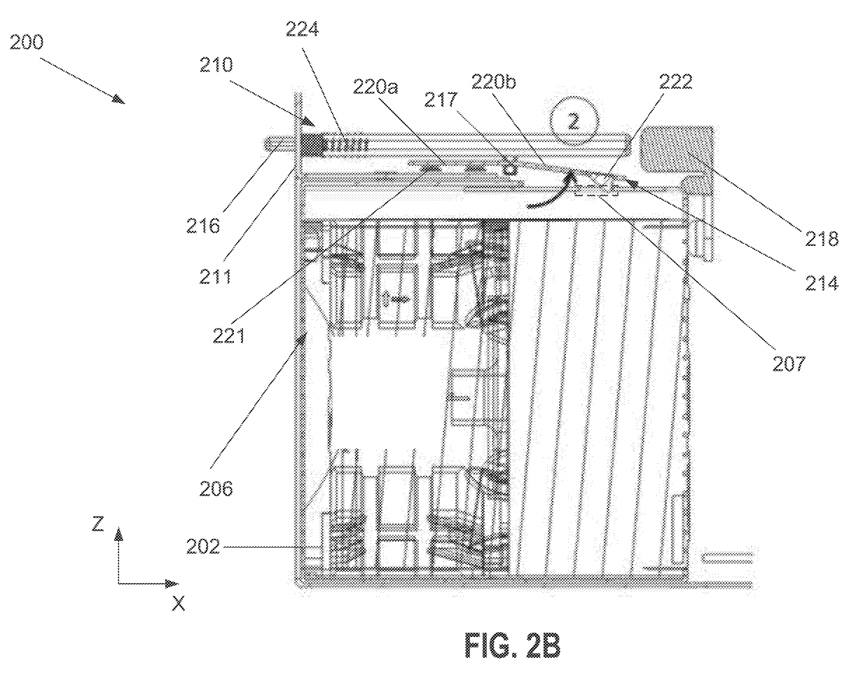

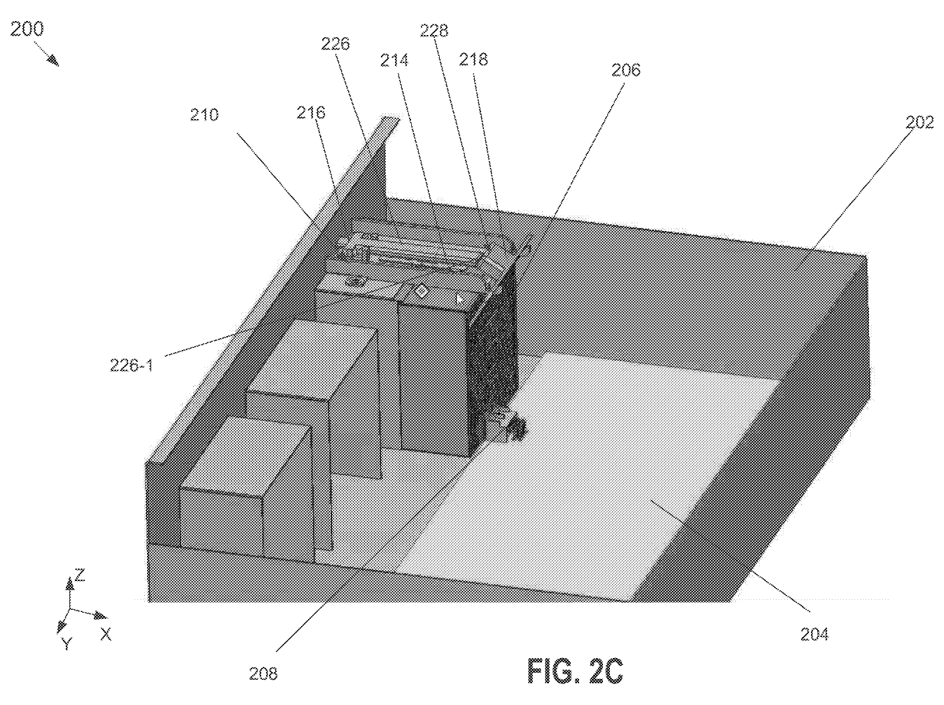

FIG. 2A is a perspective view of an example computing device 200. The computing device 200 can be same as or similar to the computing device 100 illustrated in FIG. 1.

In some implementations, as shown in FIG. 2A, the computing device 200 can include a case (or housing) 202 that is configured to hold physical components of the computing device 200. In some implementations, during operation, the case 202 is configured to secure and protect the physical components.

The computing device 200 can include a circuit board 204 (e.g., an MB 204). In some implementations, the MB 204 can be similar to, or same as, the MB 104 of the computing device 100 of FIG. 1. During operation, as illustrated in FIG. 2A, the MB 204 can be secured to the case 202 through one or more fastening elements such as screws.

The computing device 200 can include a processor attached to the MB 204. The processor can be similar to, or the same as, the processor 102 of the computing device 100 of FIG. 1. As shown in FIG. 2A, the computing device 200 further includes a physical component 206. In some implementations, the physical component 206 can be a fan module or a power supply unit (PSU). In some implementations, the fan module can be a part of the cooling module 120 of the computing device 100 of FIG. 1. For example, the cooling module 120 of the computing device 100 can include one or more fan modules (e.g., the physical component 206) that are configured to inject cooling air into the case 202. In some implementations, the power supply unit (PSU) can be similar to, or same as the power supply 108 of the computing device 100 of FIG. 1.

As shown in FIG. 2A, the MB 204 of the computing device 200 can include a connector 208. In some implementations, the physical component 206 is coupled to the MB 204 through the connector 208. For example, during operation, the MB 204 is configured to transfer power and/or control signal to the physical component 206 through the connector 208. In some implementations, the connector 208 can be a physical stopper that is configured to prevent a further movement of the physical component 206 along a horizontal direction (e.g., the X direction) during an securing process. In some implementations, the X direction can be referred to as a first direction.

In some implementations, the computing device 200 also includes a securing assembly 210 attached to the case 202. For example, as illustrated in FIG. 2A, the securing assembly 210 is attached to the case 202 through one or more rivets 212. In some implementations, the securing assembly 210 can be attached to the case 202 through soldering, one or more screws, welding, or any other suitable methods. In some implementations, the securing assembly 210 is stacked on the physical component along a vertical direction (e.g., the Z direction) intersecting with the X direction. In some implementations, the Z direction can be referred to as a second direction.

The securing assembly 210 can be configured to secure the physical component 206 to the case 202. For example, as shown in FIG. 2A, the physical component 206 is secured by a plate spring 214 of the securing assembly 210. During device operation, the plate spring 214 of the securing assembly 210 is configured to secure the physical component 206 in place, thereby improving operational stability and reducing error rates.

In some implementations, the securing assembly 210 can include a button 216 coupled to the plate spring 214 and a back plate 218. As shown in FIG. 2A, the back plate 218 is in contact with the physical component 206 while the physical component 206 is secured to the case 202 by the securing assembly 210. As shown in FIG. 2A, the back plate 218 is rotatable around a second horizontal direction (e.g., the Y direction) intersecting with the X direction and the Z direction.

As illustrated in FIG. 2A, a portion of the button 216 extends out of the case 202 while the physical component 206 is secured to the case 202 by the securing assembly 210. In some implementations, the plate spring 214 is configured to secure the physical component 206 to the case 202 at a closed position and release the physical component 206 from the case 202 at an open location. In some implementations, an operator (e.g., a human operator or a robot arm) can push the button 216 along the X direction to cause the plate spring 214 to bend from the closed position to the open location. For example, during a releasing process, the operator can push the button 216 to cause the plate spring 214 to bend from the closed position to the open location to release the physical component 206 from the case 202 and cause the back plate 218 to rotate around the Y direction, thereby pushing the physical component 206 along a direction opposite to a movement direction of the button 216 (e.g., the negative X direction).

In some implementations, a length of the portion of the button 216 that extends out of the case 202 along the X direction while the plate spring 214 is at the closed position is greater than a distance between the button 216 and the back plate 218 along the X direction while the plate spring 214 is at the closed position.

In some implementations, by utilizing the securing assembly 210 to secure a fan module to the case 202, an area of an air vent of the fan module can be maximized to ensure a high airflow of the fan module to the case 202. In other words, the securing assembly 210 can help to reduce an operating temperature of the computing device 200 during device operation.

In some implementations, during a service of maintenance operation, the operator can disassemble the physical component 206 by pushing the button 216 of the securing assembly 210. In other words, the physical component 206 can be individually controlled and serviced, thereby reduce service cost and device down time.

FIG. 2B illustrates a cross-sectional view of the example computing device 200, which can be a cross-section view of the computing device 200 of FIG. 2A along cut line AA’. As illustrated in FIG. 2B, the physical component 206 is secured to the case 202 by the securing assembly 210, where the plate spring 214 is at the closed position.

As shown in FIG. 2B, the plate spring 214 is coupled to the button 216 along the Z direction. The plate spring 214 includes a first segment 220a and a second segment 220b that is moveable with respect to the first segment 220a. The first segment 220a is attached to a cage 211 of the securing assembly 210 by one or more rivets 221. In other words, the first segment 220a of the plate spring 214 is secured to the cage 211 of the securing assembly 210 and is not moveable with respect to the cage 211.

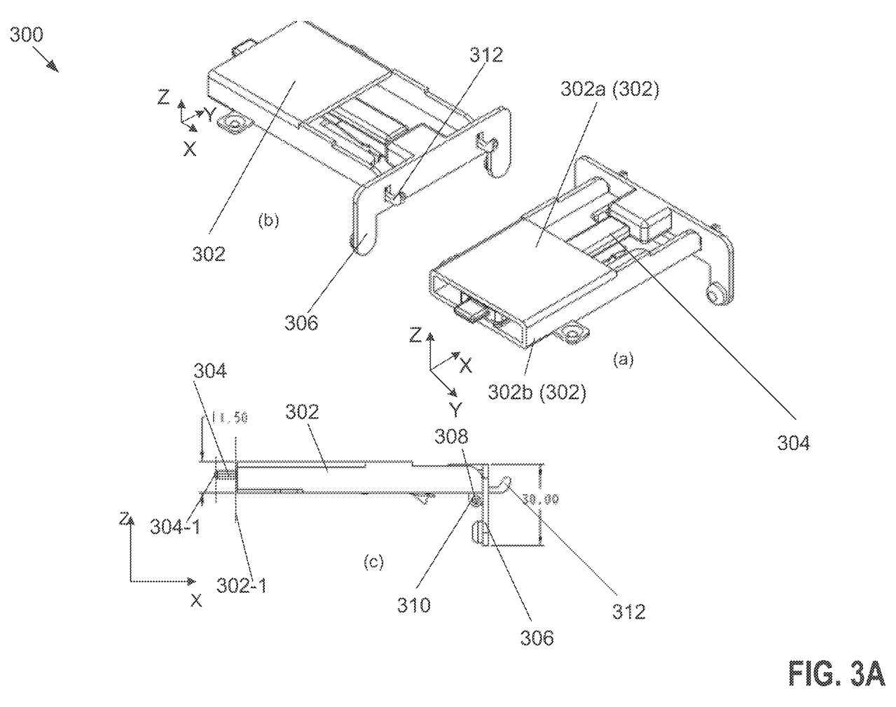

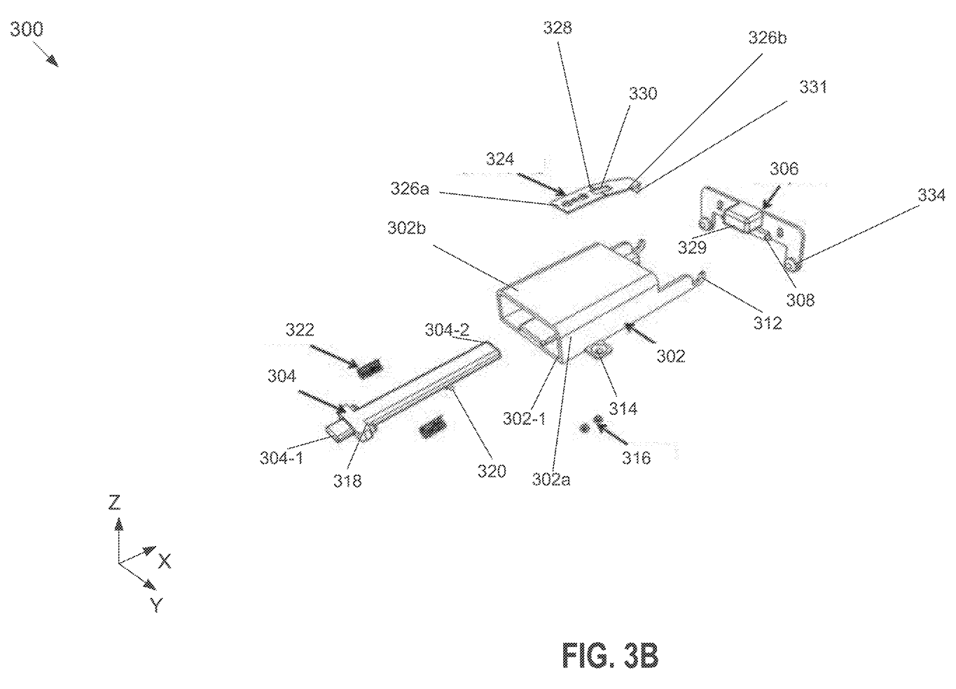

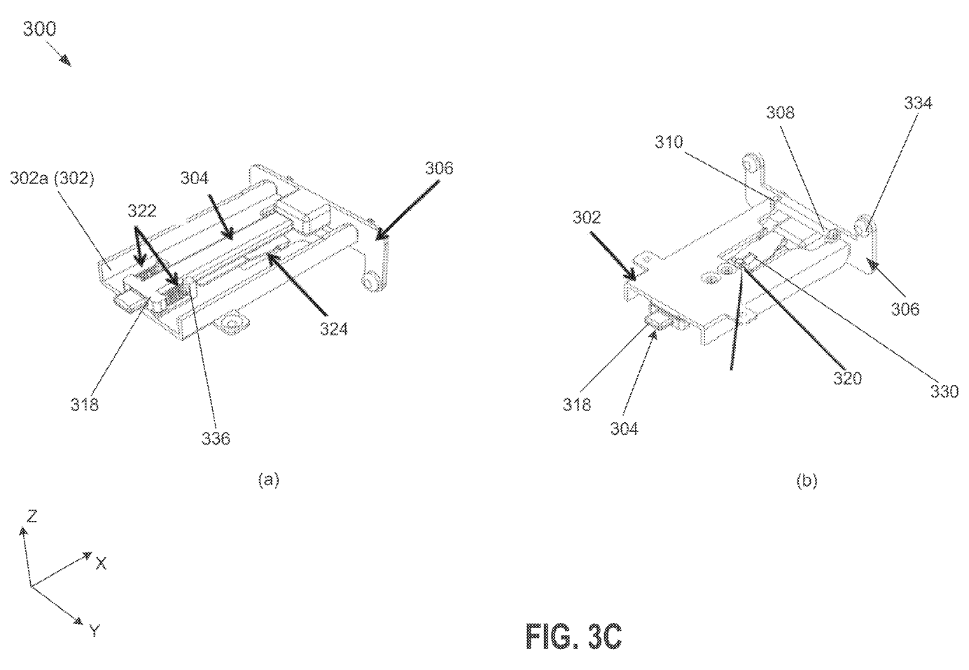

The button 216 includes a secure pin 217 that extends through a mounting hole (e.g., the mounting hole 330 of FIG. 3B) of the plate spring 214 to couple the plate spring 214 and the button 216 together. As shown in FIG. 2B, the button 216 is moveable with respect to the cage 211 along the X direction. In some implementations, the button 216 is coupled to the cage 211 of the securing assembly 210 through one or more springs 224. In some implementations, the one or more springs 224 are configured to reposition the button 216 along the X direction. In some implementations, the button 216 is configured to be moved along the X direction to cause the second segment 220b of the plate spring 214 to move with respect to the first segment 220a between the closed position and the open position.

As shown in FIG. 2B, the physical component 206 includes a secure hole 207. The second segment 220b of the plate spring 214 includes a locking structure 222. In some implementations, the locking structure 222 is configured to secure the physical component 206 to the case 202 of the computing system 200b through the secure hole 207 at the closed position. For example, as illustrated in FIG. 2B, at the closed position, a portion of the locking structure 222 extends into the secure hole 207 along the Z direction. In some implementations, the button 216 of the securing assembly 210 is not in contact with the back plate 218 along the X direction while the plate spring 214 is at the closed position. For example, the securing assembly 210 is separated from or spaced from the back plate 218 along the X direction while the plate spring 214 is at the closed position.

In some implementations, during a disassembly process of the physical component 206, the operator can push the button 216 along the X direction. A first portion of the movement of the button 216 can cause the second segment 220b of the plate spring 214 to move from the closed position to the open position, thereby releasing the physical component 206 from the case 202. A second portion of the movement of the button 216 can cause a rotation of the back plate 218 around the Y axis, thereby pushing the physical component 206 out of the case 202 along the negative X direction. In some implementations, after the disassembly process of the physical component 206, the operator can release the button 216, and the one or more springs 224 are configured to reposition the button 216 and thereby cause the second segment 220b of the plate spring 214 to move from the open position to the closed position.

FIG. 2C is another perspective view of the example computing device 200, which shows that the plate spring 214 is at the open position, in contrast with FIG. 2A or 2B where the plate spring 214 is at the closed position.

As illustrated in FIG. 2C, the button 216 can be pushed by the operator along the X direction to cause the plate spring 214 to bend from the closed position to the open location and further cause the back plate 218 to rotate around the Y axis. The rotation of the back plate 218 can move the physical component 206 along the negative X direction to decouple the connector 208 of the MB 204 and the physical component 206 along the X direction.

As shown in FIG. 2C, the button 216 includes a body structure 226. The back plate 218 includes a contact structure 228. The contact structure 228 is configured to be in contact with an end 226-1 of the body structure 226 along the X direction during a portion of a movement of the button 216 (e.g., the second portion of the movement of the button 216 as discussed in FIG. 2B above).

FIG. 3A illustrate perspective views of an example securing assembly 300. The securing assembly 300 can be similar to, or same as, the securing assembly 210 of the computing device 200 of FIG. 2A.

As illustrated in view (a) of FIG. 3A, the securing assembly 300 includes a cage 302 and a button 304. In some implementations, the cage 302 can be similar to, or same as, the cage 211 of the securing assembly 210 of FIG. 2B. In some implementations, the button 304 can be similar to, or same as, the button 216 of the securing assembly 210 of FIG. 2B.

As shown in FIG. 3A, the cage 302 includes a first portion 302a and a second portion 302b attached to the first portion 302a. In some implementations, the first portion 302a is securable to a case (e.g., the case 202 of FIG. 2A) of a computing system (e.g., the computing device 200 of FIG. 2A). As illustrated in FIG. 3A, the first and second portions 302a and 302b of the cage 302 surround the button 304 along a plane perpendicular to the X direction. In some implementations, the button 304 is movable with respect to the cage 302 along the X direction, and the first and second portions 302a and 302b of the cage 302 are configured to restrain the button 304 along the Z direction. In some implementations, the first and second portions 302a and 302b of the cage 302 is configured to prevent or limit a movement of the button 304. For example, the first portion 302a of the cage 302 is attached to the second portion 302b of the cage 302 to form an enclosed space extending along a plane (e.g., the Y-Z plane) perpendicular to the X direction. As illustrated in view (a) of FIG. 3A, the button 304 is surrounded by the enclosed space in the Y-Z plane. In some implementations, the enclosed space formed by the first and second portions 302a and 302b of the cage 302 can prevent the button 304 from moving in the Z direction.

Referring to views (b) and (c) of FIG. 3A, the securing assembly includes a back plate 306. In some implementations, the back plate 306 can be similar to, or same as, the back plate 218 of the securing assembly 210 of FIG. 2A. The back plate 306 includes a rotating rod 308. As illustrated in FIG. 3A, the back plate 306 is attached to the cage 302 by the rotating rod 308 through a pair of locking holes 310. In some implementations, e.g., as illustrated in FIG. 2C, the back plate 306 is rotatable around an axis (e.g., the Y direction) defined by the pair of locking holes 310.

As shown in the views (b) and (c) the securing assembly 300, the cage 302 further includes a positioning structure 312. The positioning structure 312 is configured to limit a range of the rotation of the back plate 306 around the axis. In some examples, a degree of the rotation of the back plate 306 is in a range from 0° to 90°.

Referring to the view (c) of FIG. 3A, the button 304 extends out of the cage 302 along the X direction. For example, a first end 304‑1 of the button 304 and an end 302‑1 of the cage 302 are offset from each other along the Z direction. The first end 304‑1 of the button 304 and the end 302‑1 of the cage 302 can be located on separate straight lines extending along the Z direction. In some implementations, e.g., as illustrated in FIGS. 2A and 2B, the first end 304‑1 of the button 304 extends out of the case (e.g., the case 202 of FIG. 2A) of a computing device (e.g., the computing device 200 of FIG. 2A), and the end 302‑1 of the cage 302 is in contact with the case of the computing device. In some implementations, the arrangement of the first end 304‑1 of the button 304 and the end 302‑1 of the cage 302 can help with an operation process of the securing assembly 300. For example (referring to the discussion of FIG. 2B above), during a releasing process of a physical component (e.g., the physical component 206 of FIG. 2B) from the computing device, an operator could push the first end 304‑1 of the button to both release the physical component from the computing device and push the physical component out of the case of the computing device.

In some examples, a length of the securing assembly 300 along the X direction is in a range between 80 mm and 130 mm. In some examples, a distance between the first and second portions 302a and 302b of the cage 302 along the Z direction is in a range between 5mm and 15mm. In some examples, a height of the back plate 306 along the Z direction is greater than 10mm.

FIG. 3B illustrates an exploded view of the securing assembly 300 of FIG. 3A. As shown in FIG. 3B, the end 302-1 and the positioning structure 312 of the cage 302 are opposite to each other along the X direction. The first portion 302a of the cage 302 includes one or more holes 314. In some implementations, e.g., as illustrated in FIG. 2A, the cage 302 is attached to the case (e.g., the case 202 of FIG. 2A) by one or more rivets 316 through the one or more holes 314. In some implementations, the first and second portions 302a and 302b of the cage 302 can include a conductive material (e.g., Cu or Al) or an insulation material (e.g., plastic).

In some implementations, e.g., as illustrated in FIG. 3B, the button 304 includes a body structure 318 extending along the X direction and a secure pin 320 attached to (or extending from) the body structure 318 along the Z direction. In some implementations, the button 304 is coupled to the cage 302 through one or more springs 322. Referring the FIG. 3B, the one or more springs 322 can be in contact with the body structure 318 of the button 304 and the cage 302. In some implementations, the button 304 is movable with respect to the cage 302 along the X direction and the one or more springs 322 are configured to reposition the button 304. In some implementations, the button 304 can include a conductive material (e.g., Cu or Al) or an insulation material (e.g., plastic). In some implementations, the one or more springs 322 can include a metal material including, but not limited to, Cu, Al, Ti, or any other suitable material.

As shown in FIG. 3B, the securing assembly 300 also includes a plate spring 324 that is configured to be coupled to the button 304 through the secure pin 320. The plate spring 324 includes a first segment 326a and a second segment 326b that is movable with respect to the first segment 326a. In some implementations, the plate spring 324 can be similar to, or the same as, the plate spring 214 of the securing assembly 210 of FIG. 2A. In some implementations, the first and second segments 326a and 326b are in contact with each other at an interface 328. The plate spring 324 is bendable at the interface 328 between the first and second segments 326a and 326b to cause a movement of the second segment 326b with respect to the first segment 326a.

Referring to the discussion of FIG. 2B, the second segment 326b of the plate spring 324 is movable between a closed position and an open position. As illustrated in FIG. 3B, the plate spring 324 also includes a mounting hole 330. In some implementations, e.g., as discussed in FIG. 2B above, the secure pin 320 is configured to extend through the mounting hole 330 to couple the plate spring 324 and the button 304 together.

In some implementations, e.g., as illustrated in FIG. 3B, the plate spring 324 also includes a locking structure 331. The locking structure 331 is configured to secure a physical component (e.g., the physical component 206 of FIG. 2A) to a computing device (e.g., the computing device 200 of FIG. 2A) while the second segment 326b of the plate spring 324 is at the closed position. In some implementations, the plate spring 324 can include a metal material including, but not limited to, Cu, Al, Ti, or any other suitable material.

As illustrated in FIG. 3B, the back plate 306 includes the rotating rod 308. Referring the FIG. 3A, the back plate 306 is attached to the cage 302 by the rotating rod 308 through the pair of locking holes (e.g., the pair of locking holes 310 of FIG. 3A), and the back plate 306 is rotatable around an axis defined by the rotating rod 308. The back plate 306 also includes a contact structure 329. In some implementations, the contact structure 329 is in contact with a second end 304-2 of the button 304 during a portion of the movement of the button 304. In some implementations, the first and second ends 304-1 and 304-2 are opposite to each other along the X direction. In some implementations, the back plate 306 also includes contact pads 334. Referring to the discussion of FIG. 2B, the contact pads 334 are in contact with the physical component of the computing device. In some implementations, the back plate 306 can include a conductive material (e.g., Cu or Al) or an insulation material (e.g., plastic). In some implementations, the contact pads 334 can include an insulation material (e.g., plastic).

FIG. 3C illustrate perspective views of the example securing assembly 300, where the second portion (e.g., the second portion 302b of FIG. 3B) is hidden to illustrate an arrangement of components of the securing assembly 300.

Referring to view (a) of FIG. 3C, the first portion 302a of the cage 302 includes a guiding pad 336. As illustrated in FIG. 3C, the one or more springs 322 are in contact with the body structure 318 of the button 304 and the guiding pad 336 of the first portion 302a of the cage 302 along the X direction. In some implementations, the one or more springs 322 are configured to limit a range of a movement of the button 304 along the X direction and configured to reposition the button 304 along the X direction.

Referring to view (b) of FIG. 3C, the secure pin 320 of the button 304 extends through the mounting hole 330 of the plate spring 324 to couple the plate spring 324 and the button 304 together. As illustrated in FIG. 3C, the plate spring 324 is between the secure pin 320 and the body structure 318 along the Z direction. Still referring to view (b) of FIG. 3C, the back plate 306 is attached to the cage 302 by the rotating rod 308 through a pair of locking holes 310. As illustrated in FIG. 3C, the back plate 306 is rotatable around an axis defined by the pair of locking holes 310.

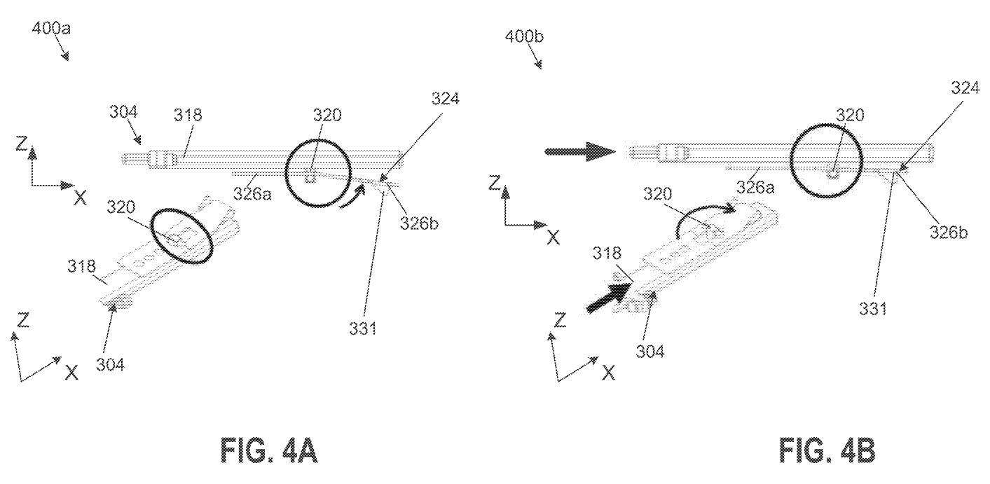

FIGS. 4A – 4B illustrate steps of releasing a physical component from a securing assembly.

FIG. 4A illustrates perspective views of the button 304 and the plate spring 324 at an initial position 400a. At the initial position 400a, the second segment 326b of the plate spring 324 is at the closed position. In some implementations, at the closed position, the locking structure 331 of the second segment 326b of the plate spring 324 is configured to secure a physical component (e.g., the physical component 206 of FIG. 2A) to a computing device (e.g., the computing device 200 of FIG. 2A).

FIG. 4B illustrates perspective views of the button 304 and the plate spring 324 at an unlocked position 400b. In some implementations, an operator (e.g., a human operator or a robot arm) can push the body structure 318 of the button 304 to move the button 304 along the X direction. As illustrated in FIG. 4B, the secure pin 320 moves along with the body structure 318. In some implementations, movement of the secure pin 320 can bend the plate spring 324 and thereby cause the second segment 326b of the plate spring 324 to move with respect to the first segment 326a of the plate spring 324 from the closed position (as illustrated in FIG. 4A) to an open position. In some implementations, at the open position, the locking structure 331 of the second segment 326b of the plate spring 324 unlocks the physical component from the computing device.

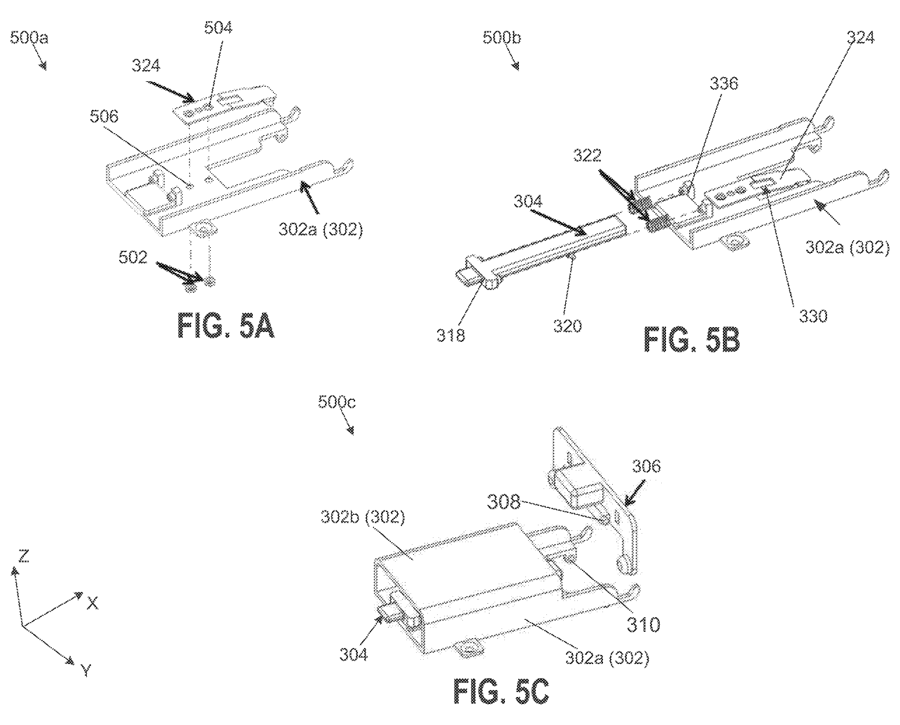

FIGS. 5A – 5C illustrate steps of assembling an example securing assembly. In some implementations, the securing assembly can be similar to, or same as, the securing assembly 210 of FIGS. 2A – 2C, the securing assembly 300 of FIGS. 3A – 3C.

As shown in FIG. 5A, step 500a is performed. At step 500a, the plate spring 324 is attached to the first portion 302a of the cage 302 through one or more rivets 502. In some implementations, the plate spring 324 can be attached to the first portion 302a of the cage 302 through soldering, one or more screws, welding, or any other suitable methods. As illustrated in FIG. 5A, the plate spring 324 includes a pair of first holes 504, and the first portion 302a of the cage 302 includes a pair of second holes 506. During step 500a, each of the pair of first holes 504 is aligned with a corresponding second hole 506 along the Z direction. Each of the one or more rivets 502 is configured to extend through a corresponding first hole 504 and a respective second hole 506 to secure the plate spring 324 to the cage 302 along the Z direction.

As shown in FIG. 5B, step 500b is performed. At step 500b, the button 304 is coupled to the cage 302 by the one or more springs 322. As shown in FIG. 5B, the one or more springs 322 are in contact with the body structure 318 of the button 304 and the guiding pad 336 of the cage 302 along the X direction. In some implementations, the secure pin 320 of the button 304 extends through the mounting hole 330 of the plate spring 324 along the Z direction.

As shown in FIG. 5C, step 500c is performed. At step 500c, the second portion 302b of the cage 302 is attached to the first portion 302a of the cage 302 along the Z direction. The back plate 306 is also attached to the cage 302. Referring to the discussion of FIG. 3A, the back plate 306 is attached to the cage 302 by the rotating rod 308 through a pair of locking holes 310.

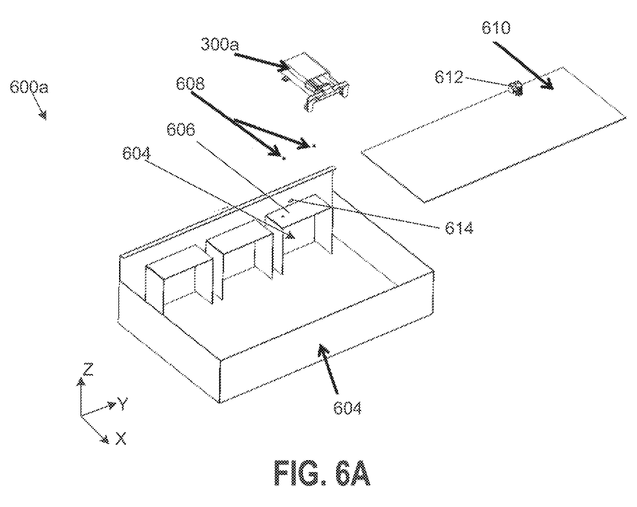

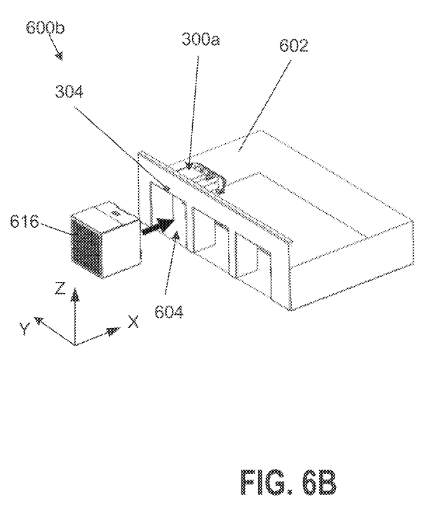

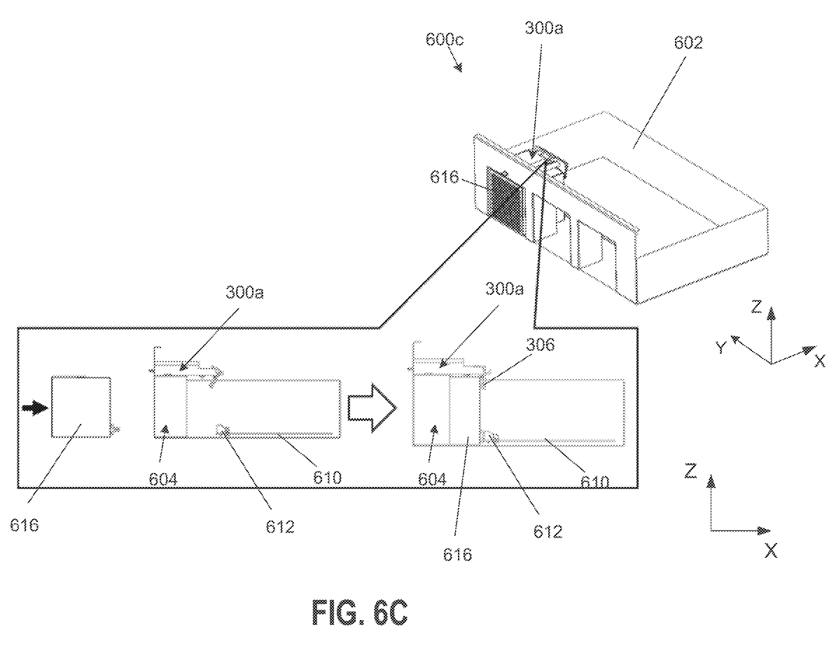

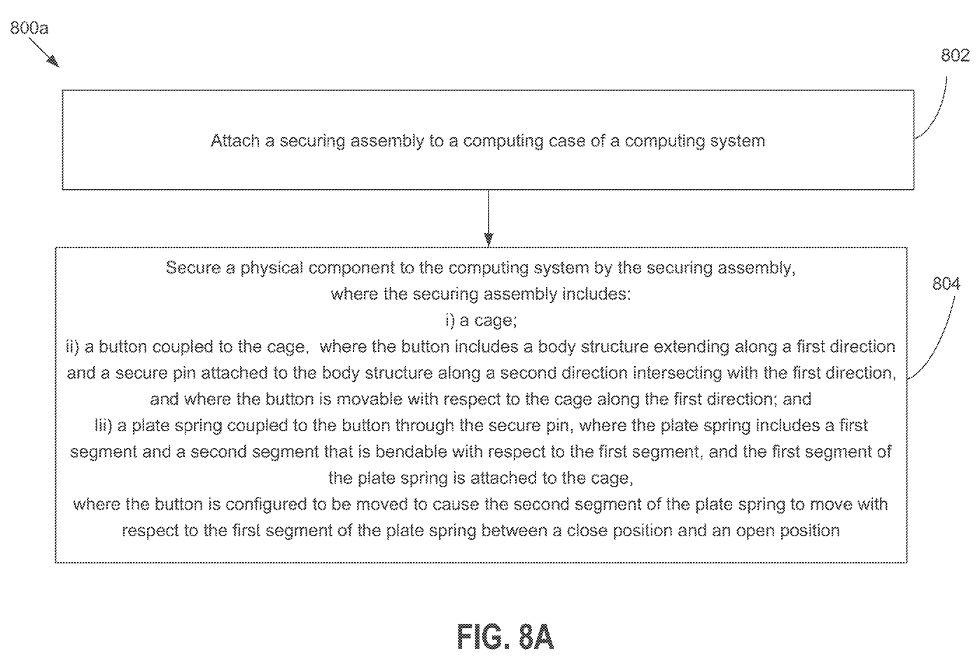

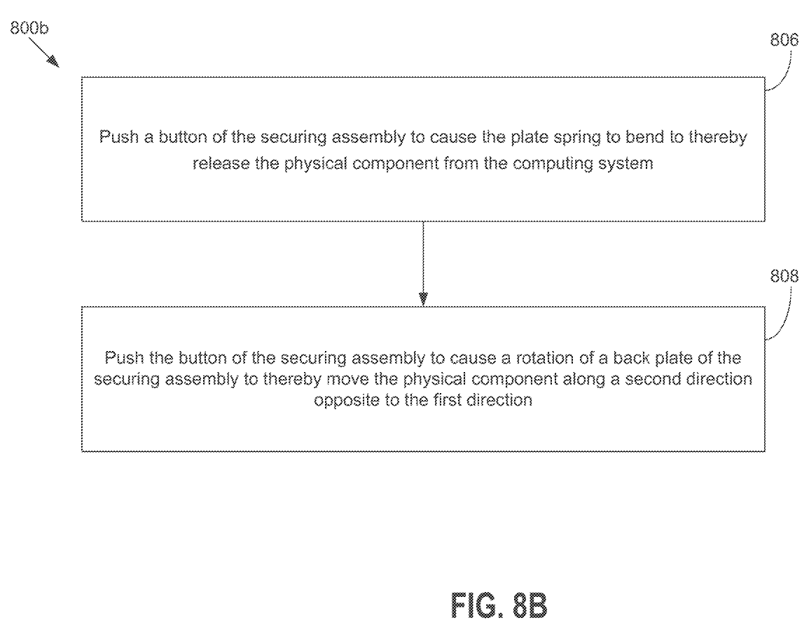

FIGS. 6A – 6C illustrate steps of securing a physical component to a computing device. FIG. 8A is a flowchart of an example process 800a of a method of securing an electrical component to a computing device. In some implementations, the securing assembly can be similar to, or same as, the securing assembly 210 of FIGS. 2A – 2C or the securing assembly 300 of FIGS. 3A – 3C. In some implementations, the physical component can be similar to, or same as, the physical component 206 of FIGS. 2A – 2C. In some implementations, the computing device, can be similar to, or same as, the computing device 200 of FIG. 2A or the computing device 200c of FIG. 2C.

At operation 802, a securing assembly (e.g., the securing assembly 210 of FIG. 2A) is attached to a computing case (e.g., the case 202 of FIG. 2A) of a computing device (e.g., the computing device 200 of FIG. 2A).

For example, referring to FIG. 6A, step 600a is performed. As shown in FIG. 6A, a case 602 includes mounting spaces 604. Each of the mounting spaces 604 includes a shielding structure 606. At step 600a, an operator (e.g., a human operator or a robot arm) can attach the securing assembly 300 to a portion of the shielding structure 606 through one or more rivets 608 along a vertical direction (e.g., the Z direction). The operator can also attach an MB 610 to the case 602. As shown in FIG. 6A, the MB 610 includes connectors 612. In some implementations, each of the mounting spaces 604 is aligned with a corresponding connector 612 along a first horizontal direction (e.g., the X direction) intersecting with the Z direction.

As shown in FIG. 6A, the case 602 also includes one or more holes 614. In some implementations, a button (e.g., the button 304 of FIG. 3B) of the securing assembly 300 extends out from a corresponding hole 614 of the case 602 along the X direction.

At operation 804, a physical component (e.g., the physical component 206 of FIG. 2A) is secured to the computing system by the securing assembly, where the securing assembly includes a cage (e.g., the cage 302 of FIG. 3B); a button (e.g., the button 304 of FIG. 3B) coupled to the cage, and a plate spring (e.g., the plate spring 324 of FIG. 3B) coupled to the button through the secure pin. The button can include a body structure (e.g., the body structure 318 of FIG. 3B) extending along a first direction (e.g., the X direction) and a secure pin (e.g., the secure pin 320 of FIG. 3B) attached to the body structure along a second direction (e.g., the Z direction) intersecting with the first direction. The button can be movable with respect to the cage along the first direction. The plate spring can include a first segment (e.g., the first segment 326a of FIG. 3B) and a second segment (e.g., the second segment 326b of FIG. 3B) that is bendable with respect to the first segment, and the first segment of the plate spring is attached to the cage. The button is configured to be moved to cause the second segment of the plate spring to move with respect to the first segment of the plate spring between a closed position and an open position.

For example, referring to FIG. 6B, step 600b is performed. As shown in FIG. 6B, the operator can push a physical component 616 into one of the mounting spaces 604.

Referring to FIG. 6C, step 600c is performed. As shown in FIG. 6C (as discussed in FIG. 2A above), the physical component 616 (e.g., the physical component 206 of FIGS. 2A-2C) is secured by the securing assembly 300 in the mounting space 604. As shown in FIG. 6C, the physical component 616 is in contact with the connector 612 along the X direction. In some implementations, the physical component 616 can be an electrical component (e.g., a fan module or a PSU), where the physical component 616 is coupled to the MB 610 through the connector 612. As shown in FIG. 6C, the back plate 306 of the securing assembly 300 is in contact with the physical component 616 while the physical component 616 is secured by the securing assembly 300.

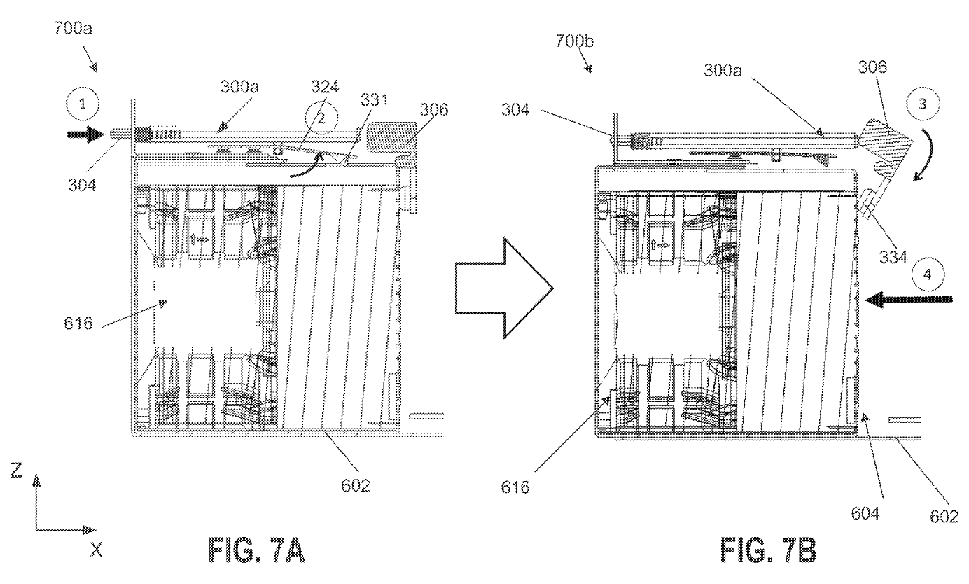

FIGS. 7A – 7B illustrate steps of releasing an electrical component from a computing device. FIG. 8B is a flowchart of an example process 800b of a method of releasing a physical component from a computing device. In some implementations, the securing assembly can be similar to, or same as, the securing assembly 210 of FIGS. 2A – 2C, the securing assembly 300 of FIGS. 3A – 3C. In some implementations, the physical component can be similar to, or same as the physical component 206 of FIGS. 2A – 2C. In some implementations, the computing device can be similar to, or same as, the computing device 200 of FIG. 2A or the computing device 200c of FIG. 2C.

At operation 806, a button (e.g., the button 304 of FIG. 3B) of the securing assembly is pushed (e.g., by a human operator or a robot arm) to cause the plate spring to bend to thereby release the physical component from the computing system.

For example, referring to FIG. 7A, step 700a is performed. As shown in FIG. 7A, the operator can push the button 304 of the securing assembly 300 along the X direction to cause the plate spring 324 to bend from a closed position to an open position to thereby release the physical component 616 from the case 602. As illustrated in FIG. 7A, the plate spring 324 includes a locking structure 331 that is configured to secure the physical component 616 to the case 602 while the plate spring 324 is at the closed position and release the physical component 616 from the case 602 while the plate spring 324 is at the open position. As illustrated in FIG. 7A, during the step 700a, the button 304 is not in contact with the back plate 306 of the securing assembly 300 along the X direction. For example, during the step 700a, the button 304 is separated from or spaced from the back plate 306 of the securing assembly 300 along the X direction.

At operation 808, the button of the securing assembly is pushed (e.g., by a human operator or a robot arm) to cause a rotation of a back plate (e.g., the back plate 306 of FIG. 3B) of the securing assembly to thereby move the physical component along a second direction opposite to the first direction.

For example, referring to FIG. 7B, step 700b is performed. As shown in FIG. 7B, the operator can keep pushing the button 304 of the securing assembly 300 along the X direction to rotate the back plate 306 of the securing assembly 300. As shown in FIG. 7B, the back plate 306 includes contact pads 334 that are in contact with the physical component 616. As illustrated in FIG. 7B, the rotation of the back plate 306 can move the physical component 616 along a direction opposite to a movement direction of the button 304(e.g., the negative X direction) through the contact pads 334 so that the physical component 616 can be pushed out of the mounting space 604 of the case 602 by the back plate 306. For example, as illustrated in FIG. 7B, the physical component 616 and the button 304 move in opposite directions along the X direction.

In some implementations, the plate spring includes a first hole (e.g., the mounting hole 330 of FIG. 3B), where the secure pin extends through the first hole to couple the plate spring and the button together, the plate spring being between the body structure and the secure pin along the second direction, and where the plate spring is configured to be bended by a movement of the button along the first direction to cause the second segment to move with respect to the first segment, with the secure pin coupling together the plate spring and the button.

In some implementations, the first segment of the plate spring is secured to the cage through one or more rivets.

In some implementations, the plate spring is bendable at an interface (e.g., the interface 328 of FIG. 3B) between the first segment and the second segment of the plate spring to cause a movement of the second segment with respect to the first segment.

In some implementations, the button is coupled to the cage through a pair of springs (e.g., the one or more springs 322 of FIG. 3B), where the pair of springs are in contact with the body structure of the button and a guiding pad (e.g., the guiding pad 336 of FIG. 3C) of the cage, and where the pair of springs and the guiding pad are configured to limit a range of a movement of the button along the first direction, and where the pair of springs are configured to reposition the button along the first direction.

In some implementations, the cage includes a first portion (e.g., the first portion 302a of FIG. 3B) securable to a computing system; and a second portion (e.g., the second portion 302b of FIG. 3B) attached to the first portion, where the first portion and the second portion of the cage surround the button along a plane perpendicular to the first direction, and are configured to restrain the button along the second direction.

In some implementations, the second segment of the plate spring includes a locking structure (e.g., the locking structure 331 of FIG. 3B) that is configured to secure the physical component to the computing system at the closed position.

In some implementations, the back plate is attached to the cage by a rotating rod (e.g., the rotating rod 308 of FIG. 3B) through a pair of locking holes (e.g., the pair of locking holes 310 of FIG. 3A), and the back plate is rotatable around an axis defined by the pair of locking holes.

In some implementations, the button is configured to be moved to cause the rotation of the back plate around the axis while the plate spring at the open position, with the back plate being in contact with an end of the body structure of the button along the first direction.

In some implementations, the back plate includes a pair of contact pads (e.g., the contact pads 334 of FIG. 3B) that are in contact with the electrical component, and where the electrical component is movable along a direction opposite to a movement direction of the button by the pair of contact pads in reaction to the rotation of the back plate.

In some implementations, the cage includes at least one positioning structure (e.g., the positioning structure 312 of FIG. 3B) configured to limit a range of a rotation of the back plate around the rotating rod.

In some implementations, a degree of the rotation of the back plate is in a range from 0° to 90°.

In some implementations, the button is not in contact with the back plate along the first direction, while the plate spring is at the closed position.

In some implementations, the button is configured to be moved to cause the rotation of the back plate around the axis while the plate spring is at the open position, with the back plate being in contact with an end of the body structure of the button along the first direction.

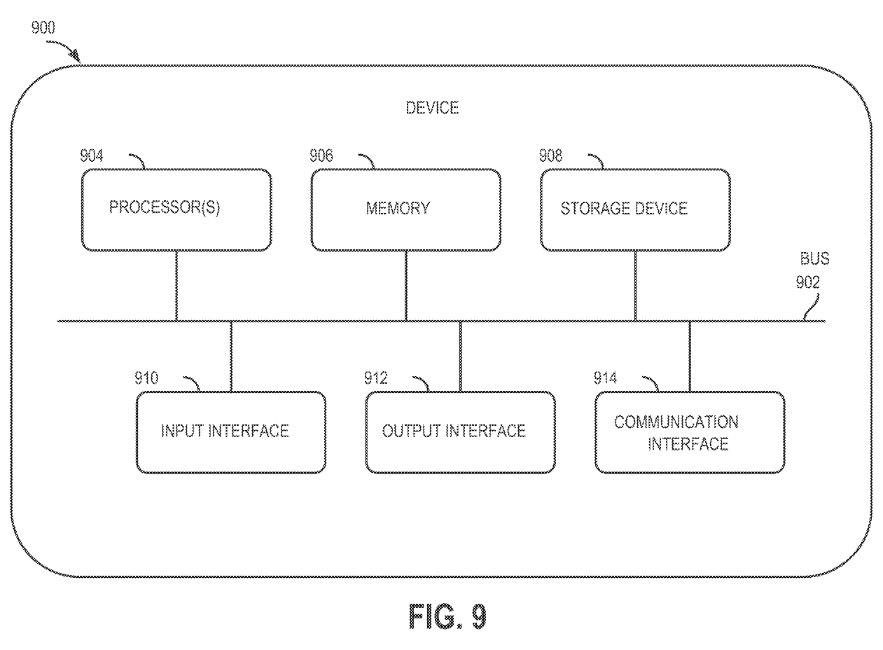

FIG. 9 is a block diagram illustrating an example architecture of a computing device 900 used to provide computational functionalities associated with described algorithms, methods, functions, processes, flows, and procedures. Other architectures are possible, including architectures with more or fewer components. The computing device can be implemented as the computing device 100 of FIG. 1 or the computing device 200 of FIGS. 2A-2C. The computing device 900 includes processor 904, memory 906, storage component 908, input interface 910, output interface 912, communication interface 914, and bus 902.

Bus 902 includes a component that permits communication among the components of the computing device 900. In some embodiments, processor 904 is implemented in hardware, software, or a combination of hardware and software. In some examples, processor 904 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 906 includes random access memory (RAM), read-only memory (ROM), and/or another type of dynamic and/or static storage device (e.g., flash memory, magnetic memory, optical memory, and/or the like) that stores data and/or instructions for use by processor 904.

Storage component 908 stores data and/or software related to the operation and use of the computing device 900. In some examples, storage component 908 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 910 includes a component that permits the computing device 900 to receive information, such as via user input (e.g., a touchscreen display, a keyboard, a keypad, a mouse, a button, a switch, a microphone, a camera, and/or the like). Additionally or alternatively, in some embodiments input interface 910 includes a sensor that senses information (e.g., a global positioning system (GPS) receiver, an accelerometer, a gyroscope, an actuator, and/or the like). Output interface 912 includes a component that provides output information from the computing device 900 (e.g., a display, a speaker, one or more light-emitting diodes (LEDs), and/or the like).

In some embodiments, communication interface 914 includes a transceiver-like component (e.g., a transceiver, a separate receiver and transmitter, and/or the like) that permits the computing device 900 to communicate with other devices via a wired connection, a wireless connection, or a combination of wired and wireless connections. In some examples, communication interface 914 permits the computing device 900 to receive information from another device and/or provide information to another device. In some examples, communication interface 914 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, the computing device 900 performs one or more processes described herein. The computing device 900 performs these processes based on processor 904 executing software instructions stored by a computer-readable medium, such as memory 906 and/or storage component 908. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 906 and/or storage component 908 from another computer-readable medium or another device via communication interface 914. When executed, software instructions stored in memory 906 and/or storage component 908 cause processor 904 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 906 and/or storage component 908 includes data storage or at least one data structure (e.g., a database and/or the like). The computing device 900 is capable of receiving information from, storing information in, communicating information to, or searching information stored in the data storage or the at least one data structure in memory 906 or storage component 908. In some examples, the information includes network data, input data, output data, or any combination thereof.

In some embodiments, the computing device 900 is configured to execute software instructions that are either stored in memory 906 and/or in the memory of another device (e.g., another device that is the same as or similar to the computing device 900). As used herein, the term “module” refers to at least one instruction stored in memory 906 and/or in the memory of another device that, when executed by processor 904 and/or by a processor of another device (e.g., another device that is the same as or similar to the computing device 900) cause the computing device 900 (e.g., at least one component of the computing device 900) to perform one or more processes described herein. In some embodiments, a module is implemented in software, firmware, hardware, and/or the like.

The number and arrangement of components illustrated in FIG. 9 are provided as an example. In some embodiments, the computing device 900 can include additional components, fewer components, different components, or differently arranged components than those illustrated in FIG. 9. Additionally, or alternatively, a set of components (e.g., one or more components) of the computing device 900 can perform one or more functions described as being performed by another component or another set of components of the computing device 900.

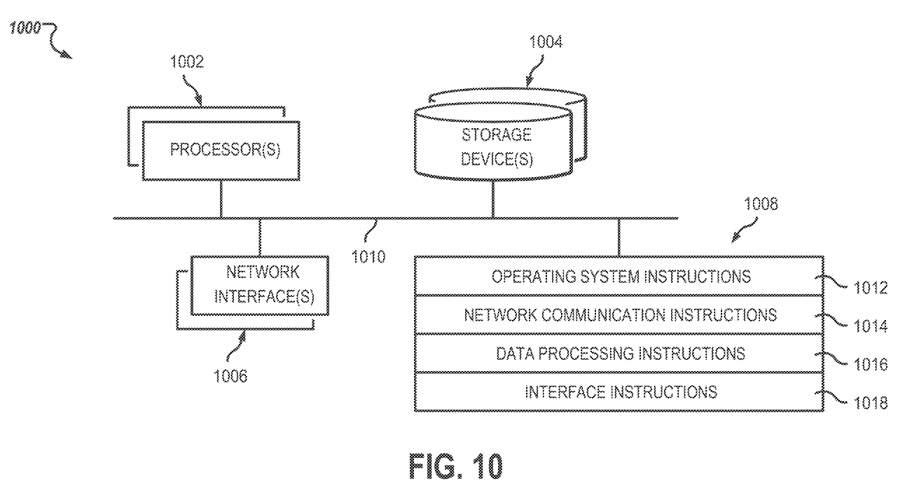

FIG. 10 illustrates an example architecture 1000 of a computing system used to provide computational functionalities associated with described algorithms, methods, functions, processes, flows, and procedures. The computing system can include one or more computing devices such as the computing device 100 of FIG. 1 or the computing device 200 of FIG. 2A-2C. Other architectures are possible, including architectures with more or fewer components.

In some implementations, architecture 1000 includes one or more processor(s) 1002 (e.g., dual-core Intel® Xeon® Processors), one or more network interface(s) 1006, one or more storage device(s) 1004 (e.g., hard disk, optical disk, flash memory) and one or more computer-readable medium(s) 1008 (e.g., hard disk, optical disk, flash memory, etc.). These components can exchange communications and data over one or more communication channel(s) 1010 (e.g., buses), which can utilize various hardware and software for facilitating the transfer of data and control signals between components.

The term “computer-readable medium” refers to any medium that participates in providing instructions to the processor(s) 1002 for execution, including without limitation, non-volatile media (e.g., optical or magnetic disks), volatile media (e.g., memory) and transmission media. Transmission media includes, without limitation, coaxial cables, copper wire, and fiber optics.

Computer-readable medium(s) 1008 can further include instructions 1012 for an operating system (e.g., Mac OS® server, Windows® NT server, Linux Server), instructions 1014 for network communications module, data processing instructions 1016, and interface instructions 1018.

Operating systems can be multi-user, multiprocessing, multitasking, multithreading, real time, etc. Operating system performs basic tasks, including but not limited to: recognizing input from and providing output to devices 1002, 1004, 1006 and 1008; keeping track and managing files and directories on computer-readable medium(s) 1008 (e.g., memory or a storage device); controlling peripheral devices; and managing traffic on the one or more communication channel(s) 1010. Network communications module includes various components for establishing and maintaining network connections (e.g., software for implementing communication protocols, such as TCP/IP, HTTP, etc.) and for creating a distributed streaming platform using, for example, Apache Kafka™. Data processing instructions 1016 include server-side or backend software for implementing the server-side operations. Interface instructions 1018 includes software for implementing a web server and/or portal for sending and receiving data to and from user side computing devices and service provider side computing devices.

Architecture 1000 can be implemented by a cloud computing system and can be included in any computing device, including one or more server computers in a local or distributed network each having one or more processing cores. Architecture 1000 can be implemented in a parallel processing or peer-to-peer infrastructure or on a single device with one or more processors. Software can include multiple software components or can be a single body of code.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual’s action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application-specific integrated circuit (ASIC). In some implementations, the computer or computer-implemented system or special-purpose logic circuitry (or a combination of the computer or computer-implemented system and special-purpose logic circuitry) can be hardware- or software-based (or a combination of both hardware- and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer-readable media for storing computer program instructions and data can include all forms of permanent/non-permanent or volatile/non-volatile memory, media and memory devices, including by way of example semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto-optical disks; and optical memory devices, for example, digital versatile/video disc (DVD), compact disc (CD)-ROM, DVD+/-R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user’s mobile computing device in response to requests received from the web browser).

The term “graphical user interface (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 902.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances.

As used herein, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or, A and B.” As used herein, the term “and/or” as used herein refers to and encompasses any and all possible combinations of one or more of the associated listed terms. For example, the term “A and/or B” means that either option A, option B, or both options A and B are possible, where A and B may be singular or plural.

As used herein, the term “about” or “approximately” can allow for a degree of variability in a value or range, for example, within 10%, within 5%, or within 1% of a stated value or of a stated limit of a range. As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

In addition, the phraseology or terminology employed in the present disclosure, and not otherwise defined, is for the purpose of description only and not of limitation. Any use of section headings is intended to aid reading of the document and is not to be interpreted as limiting; information that is relevant to a section heading may occur within or outside of that particular section.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

The breadth and scope of the present disclosure should not be limited by any of the above-described exemplary implementations, but should be defined only in accordance with the following claims and their equivalents.

1. An apparatus, comprising: a cage; a button coupled to the cage, wherein the button comprises a body structure extending along a first direction and a secure pin attached to the body structure along a second direction intersecting with the first direction, and wherein the button is movable with respect to the cage along the first direction; and a plate spring coupled to the button through the secure pin, wherein the plate spring comprises a first segment and a second segment that is movable with respect to the first segment, and the first segment of the plate spring is attached to the cage, wherein the button is configured to be moved to cause the second segment of the plate spring to move with respect to the first segment of the plate spring between a closed position and an open position.

2. The apparatus of claim 1, wherein the plate spring comprises a mounting hole, wherein the secure pin extends through the mounting hole to couple the plate spring and the button together, the plate spring being between the body structure and the secure pin along the second direction, and wherein the plate spring is configured to be bended by a movement of the button along the first direction to cause the second segment to move with respect to the first segment, with the secure pin coupling together the plate spring and the button.

3. The apparatus of claim 1, wherein the first segment of the plate spring is secured to the cage through one or more rivets.

4. The apparatus of claim 1, wherein the plate spring is bendable at an interface between the first segment and the second segment of the plate spring to cause a movement of the second segment with respect to the first segment.

5. The apparatus of claim 1, wherein the button is coupled to the cage through a pair of springs, wherein the pair of springs are in contact with the body structure of the button and a guiding pad of the cage, and wherein the pair of springs and the guiding pad are configured to limit a range of a movement of the button along the first direction, and
wherein the pair of springs are configured to reposition the button along the first direction.

6. The apparatus of claim 1, wherein the cage comprises: a first portion securable to a computing system; and a second portion attached to the first portion,
wherein the first portion and the second portion of the cage surround the button along a plane perpendicular to the first direction, and are configured to restrain the button along the second direction.

7. The apparatus of claim 6, wherein the second segment of the plate spring comprises a locking structure that is configured to secure a physical component to the computing system at the closed position.

8. The apparatus of claim 1, further comprising: a back plate comprising a rotating rod, wherein the back plate is attached to the cage by the rotating rod through a pair of locking holes, and the back plate is rotatable around an axis defined by the pair of locking holes.

9. The apparatus of claim 8, wherein the cage comprises at least one positioning structure configured to limit a range of a rotation of the back plate around the axis.

10. The apparatus of claim 8, wherein the button is not in contact with the back plate along the first direction, while the plate spring is at the closed position.

11. The apparatus of claim 10, wherein the button is configured to be moved to cause the rotation of the back plate around the axis while the plate spring is at the open position, with the back plate being in contact with an end of the body structure of the button along the first direction.

12. A computing system, comprising: a computing case; and a securing assembly attached to the computing case, wherein the securing assembly comprises: a cage that is attached to the computing case; a button coupled to the cage, wherein the button comprises a body structure extending along a first direction and a secure pin attached to the body structure along a second direction intersecting with the first direction, and wherein the button is movable with respect to the cage along the first direction; and a plate spring coupled to the button through the secure pin, wherein the plate spring comprises a first segment and a second segment that is bendable with respect to the first segment, and the first segment of the plate spring is attached to the cage, wherein the button is configured to be moved to cause the second segment of the plate spring to move with respect to the first segment of the plate spring between a closed position and an open position.

13. The computing system of claim 12, further comprising: an electrical component, where the electrical component is configured to be secured to the computing case of the computing system by the securing assembly.

14. The computing system of claim 13, wherein the second segment of the plate spring comprises a locking structure that is configured to secure the electrical component to the computing case at the closed position.

15. The computing system of claim 14, further comprising: an electrical board attached to the computing case; and a connector coupled to the electrical board, wherein the electrical component is connected to the connector while the electrical component is secured by the second segment of the plate spring.

16. The computing system of claim 13, further comprising:
a back plate comprising a rotating rod, wherein the back plate is attached to the cage by the rotating rod through a pair of locking holes, and the back plate is rotatable around an axis defined by the pair of locking holes.

17. The computing system of claim 16, wherein the button is configured to be moved to cause the rotation of the back plate around the axis while the plate spring at the open position, with the back plate being in contact with an end of the body structure of the button along the first direction.

18. The computing system of claim 17, wherein the back plate comprises a pair of contact pads that are in contact with the electrical component, and wherein the electrical component is movable along a direction opposite to a movement direction of the button by the pair of contact pads in reaction to the rotation of the back plate.

19. A method, comprising: securing a physical component to a computing system by a securing assembly, wherein the securing assembly comprises: a cage, a button coupled to the cage, and a plate spring coupled to the button, wherein the button comprises a body structure extending along a first direction and a secure pin attached to the body structure along a second direction intersecting with the first direction, wherein the button is movable with respect to the cage along the first direction, wherein a plate spring coupled to the button through the secure pin, wherein the plate spring comprises a first segment and a second segment that is movable with respect to the first segment, and the first segment of the plate spring is attached to the cage, and wherein the button is configured to be moved to cause the second segment of the plate spring to move with respect to the first segment of the plate spring between a closed position and an open position; and
releasing the physical component from the computing system by pushing a button of the securing assembly to cause the plate spring to bend to thereby release the physical component from the computing system.

20. The method of claim 19, wherein releasing the physical component from the computing system comprises: pushing the button of the securing assembly to cause a rotation of a back plate of the securing assembly to thereby move the physical component along a second direction opposite to the first direction.
